(19) United States
(12) Patent Application Publication
(10) Pub. No.: US 2026/0181765 A1
(43) Pub. Date: Jun. 25, 2026

(54) PHASE MEASUREMENT AND CONTROL IN LINEAR ACCLERATOR

(71) Applicant: Applied Materials, Inc., Santa Clara, CA (US)

(72) Inventors: Joshua Matthew Jones, Penfield, NY (US); Aung Toe, Newton, MA (US); Michael Lawrence Kirk, Bloomfield, NY (US); David J. Coumou, Webster, NY (US); James Maki, BOVEY, MN (US); Scott E. Peitzsch, Tewksbury, MA (US); Matthew J. Kenyon, Rochester, NY (US)

(73) Assignee: Applied Materials, Inc., Santa Clara, CA (US)

(21) Appl. No.: 18/987,017

(22) Filed: Dec. 19, 2024

(51) Int. Cl. H05H 9/04; G01R 29/08; H05H 7/02; H05H 7/04

(52) U.S. Cl. CPC H05H 9/042; G01R 29/0892; H05H 7/02; H05H 7/04; H05H 2007/025; H05H 2007/041

(57) ABSTRACT

A linear accelerator. The linear accelerator may include a buncher to generate a bunched particle beam from a charged particle beam, and a plurality of acceleration stages, to accelerate the bunched particle beam. The linear accelerator may further include a phase control system, to individually measure a phase of an RF signal that is applied at a first frequency to a given acceleration stage of the plurality of acceleration stages. The phase control system may include an RF signal pickup assembly, comprising a plurality of RF signal detectors, arranged separately in the plurality of acceleration stages. The phase control system may further include a phase measurement circuit, to convert an RF pickup signal, received from an RF signal detector of the RF pickup assembly, into a digital baseband signal, for determining a phase of the RF signal.

### FIELD OF THE DISCLOSURE

The disclosure relates generally to linear accelerators and more particularly to multi-stage RF linear accelerators.

### BACKGROUND OF THE DISCLOSURE

RF linear accelerators (LINAC) are used to accelerate charged particle beams. The charged particle beam may be accelerated through a series of acceleration stages by the application of an RF electric field to the charged particle beam while passing through the LINAC. Particle beam processing apparatus that employ LINACs include, for example, electron beam linear accelerators and ion implanters that employ an ion beam linear accelerator.

Ion implantation is a process of introducing dopants or impurities into a substrate via bombardment. Ion implantation systems may comprise an ion source and a series of beam-line components. The ion source may comprise a chamber where ions are generated. One type of ion implanter suitable for generating ion beams of medium energy and high energy uses an RF LINAC, where a series of electrodes arranged as tubes around the ion beam are provided to accelerate the ion beam to increasingly higher energy along the succession of tubes. The various electrodes may be arranged in a series of stages where a given electrode in a given stage receives an AC voltage signal, an in particular, a radio frequency voltage (RF voltage) to accelerate the ion beam.

### BRIEF SUMMARY

In one embodiment, a particle beam processing apparatus is provided. The particle beam processing apparatus may include a particle beam source to generate a charged particle beam, and a linear accelerator to generate a bunched particle beam from the charged particle beam, and accelerate the bunched particle beam. The linear accelerator may include a plurality of acceleration stages that accelerate the bunched particle beam, and a phase control system, to individually measure a phase of an RF signal that is applied at a first frequency to a given acceleration stage of the plurality of acceleration stages. The phase control system may include an RF signal pickup assembly, comprising a plurality of RF signal detectors, arranged separately in the plurality of acceleration stages. The phase control system may also include a phase measurement circuit, to convert an RF pickup signal, received from an RF signal detector of the RF pickup assembly, into a digital signal, for determining a phase of the RF signal.

In a further embodiments, a method of operating a particle beam processing apparatus is provided. The method may include generating a continuous charged particle beam, bunching the continuous charged particle beam into a bunched particle beam, and accelerating the bunched particle beam in a linear accelerator that comprises a plurality of acceleration stages. The method may also include measuring a phase of an RF signal that is applied at a first frequency to a given acceleration stage of the plurality of acceleration stages. The measuring the phase may include receiving a RF pickup signal from a signal detector of the given acceleration stage, and converting the RF pickup signal to a digital baseband signal.

In a further embodiment, a linear accelerator is provided. The linear accelerator may include a buncher to generate a bunched particle beam from a charged particle beam, and a plurality of acceleration stages, to accelerate the bunched particle beam. The linear accelerator may further include a phase control system, to individually measure a phase of an RF signal that is applied at a first frequency to a given acceleration stage of the plurality of acceleration stages. The phase control system may include an RF signal pickup assembly, comprising a plurality of RF signal detectors, arranged separately in the plurality of acceleration stages. The phase control system may further include a phase measurement circuit, to convert an RF pickup signal, received from an RF signal detector of the RF pickup assembly, into a digital baseband signal, for determining a phase of the RF signal

### BRIEF DESCRIPTION OF THE DRAWINGS

FIG. 1 shows an exemplary ion implantation system, according to embodiments of the disclosure;

FIG. 2 shows an exemplary acceleration stage together with a phase measurement arrangement;

FIG. 3 shows details of an exemplary phase measurement circuit;

FIG. 4 shows an exemplary process flow, according to some embodiments; and

FIG. 5 depicts another exemplary process flow according to some embodiments of the disclosure.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

### DETAILED DESCRIPTION

An apparatus, system and method in accordance with the present disclosure will now be described more fully hereinafter with reference to the accompanying drawings, where embodiments of the system and method are shown. The system and method may be embodied in many different forms and are not be construed as being limited to the embodiments set forth herein. Instead, these embodiments are provided so this disclosure will be thorough and complete, and will fully convey the scope of the system and method to those skilled in the art.

As used herein, an element or operation recited in the singular and proceeded with the word “a” or “an” are understood as potentially including plural elements or operations as well. Furthermore, references to “one embodiment” of the present disclosure are not intended to be interpreted as precluding the existence of additional embodiments also incorporating the recited features.

RF LINACs (generally referred to herein as “LINACs”) employ initial portions of the LINAC as so-called buncher(s) that bunch an initially-continuous charged particle beam into a bunched particle beam. A given acceleration stage of the LINAC is used to increase ion energy by accelerating bunched electrons or ions, for example. A separate RF assembly may be provided for each acceleration stage, which assembly may include an RF power supply, network, and resonator for generating an RF voltage that is applied to a given electrode or set of electrodes at the given acceleration stage. The RF voltage that is supplied to a drift tube electrode of the acceleration stage generates an oscillating electric field that is coupled into a bunched particle beam being conducted through the LINAC.

In order to efficiently transport and focus a charged particle beam through the multiple acceleration stages of LINAC, accounting for the phase difference between RF voltages signals sent to the different acceleration stages is useful. To obtain the desired phase at different acceleration stages, known linear accelerators may employ a time-consuming calibration process for each RF assembly of the LINAC. For example, (neglecting an RF assembly for a buncher stage) a LINAC having 10 acceleration stages will employ 10 separate RF assemblies that are calibrated using an external measurement device.

With respect to these and other considerations, the present disclosure is provided.

Provided herein are approaches for improved linear accelerator measurement and control, for controlling charged particle beams, including control of LINACs for improved high energy ion implantation systems, based upon a beamline architecture using a linear accelerator. For brevity, an ion implantation system may also be referred to herein as an “ion implanter,” and a charged particle beam may be referred to as a “particle beam.” Various embodiments provide novel configurations for providing the capability of generating high energy ions, where the final ion energy delivered to a substrate may be 300 keV, 500 keV, 1 MeV or greater. In exemplary embodiments, a phase measurement arrangement and techniques are provided for improved processing of a charged particle beam in a LINAC.

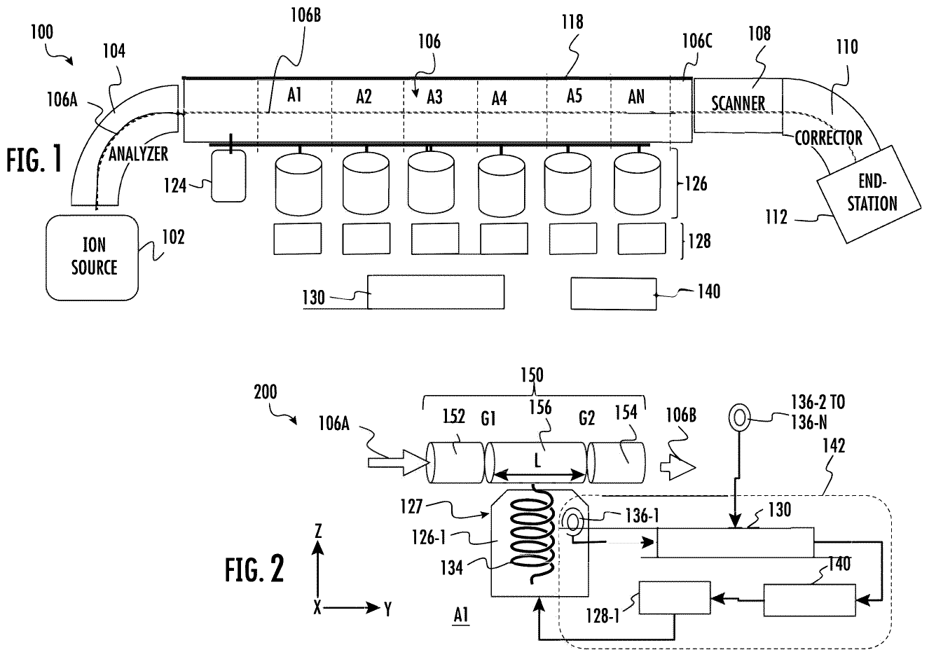

FIG. 1 depicts a schematic of an ion implanter apparatus, according to embodiments of the disclosure. The ion implanter 100, may represent a beamline ion implanter, with some elements not shown for clarity of explanation. The ion implanter 100 may include an ion source 102, as known in the art. The ion source 102 may include an extraction system including extraction components and filters (not shown) to generate an ion beam 106 at a first energy. Examples of suitable ion energy for the first ion energy range from 5 keV to 300 keV, while the embodiments are not limited in this context. To form a high energy ion beam, the ion implanter 100 may include various additional components for accelerating the ion beam 106. As output by the ion source 102, the ion beam may be a continuous ion beam 106A.

The ion implanter 100 may include an analyzer 104, functioning to analyze the ion beam 106 as in known apparatus, by changing the trajectory of the ion beam 106, as shown. The ion implanter 100 may also include a buncher 124, which component may form an upstream part of an RF linear accelerator, shown as LINAC 118. The buncher 124 may be arranged as in known apparatus, to output the continuous ion beam 106A as a bunched ion beam 106B. The LINAC 118 may include various acceleration stages to accelerate the bunched ion beam 106B by application of an RF signal at the different stages. The LINAC may output the bunched ion beam 106B as a high energy ion beam 106C. The ion implanter 100 may include various additional components, such as a scanner 108, to scan the high energy ion beam 106C, such as in a transverse direction to a direction of propagation of the high energy ion beam 106C. The ion implanter may further include components such as a corrector 110 and end station 112, as known in the art.

To impart a target final energy to the high energy ion beam 106C, the LINAC 118 may include a series of RF assemblies, where a given RF assembly is arranged with a dedicated RF supply to deliver a given RF signal to a given acceleration stage of the LINAC 118. The different acceleration stages of LINAC 118 are identified as acceleration stage A1, acceleration stage A2, acceleration stage A3, acceleration stage A4, acceleration stage A5, and acceleration stage AN. However, according to other embodiments, the LINAC 118 may have fewer acceleration stages or a greater number of acceleration stages, where the acceleration stage AN may represent the last, most downstream, acceleration stage that outputs the high energy ion beam 106C at a highest beam energy. A given acceleration stage of the acceleration stages of LINAC 118 may be coupled to a dedicated RF assembly that includes an RF power source (not separately shown) that generates an RF signal to power the given acceleration stage. The RF signal is fed to a resonator circuit, or “resonator,” which circuit couples an RF voltage to an electrode in the given acceleration stage, as detailed with respect to FIG. 2. These resonator circuits are designated as resonators 126 in FIG. 1. As the bunched ion beam 106B passes through successive acceleration stages of the LINAC 118, the bunched ion beam 106B will be accelerated to a high energy, based upon the number of acceleration stages and the amplitude of the RF voltage applied by a given resonator 126 at each acceleration stage.

The ion implanter 100 further includes a power arrangement 128 that provides power to the acceleration stages of the LINAC 118. The power arrangement 128 may include dedicated RF power assemblies, where a given RF power assembly is coupled to deliver power to a given acceleration stage, as noted above and as discussed further below. Additionally, the ion implanter 100 may include a phase measurement circuit 130, and phase controller 140, where the operation of these components is further discussed below.

To illustrate how energy is coupled into a bunched ion beam, FIG. 2 depicts details of an exemplary acceleration stage, shown as acceleration stage A1, which stage may be representative of any of the acceleration stages (A1-AN) shown in FIG. 1. Also shown in FIG. 2 is a phase control system 142 to control operation of the various stages of a LINAC, such as LINAC 118. The acceleration stage A1 may include a drift tube assembly 150, as well as a resonator 126-1. In various non-limiting embodiments the drift tube assembly 150 may be a double gap configuration or a triple gap configuration. The configuration explicitly shown in FIG. 2 is a double gap configuration. In this arrangement, the drift tube assembly 150 includes a first grounded drift tube 152, a second grounded drift tube 154, and a powered drift tube 156. As suggested, the first grounded drift tube 152 and the second grounded drift tube 154 may be coupled to ground potential. The powered drift tube 156 is coupled to a resonator coil 134 that delivers an RF voltage signal, which RF voltage signal causes an RF field to develop in the gap G1 between the first grounded drift tube 152 and the powered drift tube 156, as well as an RF field in the gap G2 between the powered drift tube 156 and the second grounded drift tube 154. The timing of the phase of an RF signal as applied to the powered drift tube 156 will affect how an ion bunch that passes through gap G1 or gap G2 is accelerated by the acceleration stage.

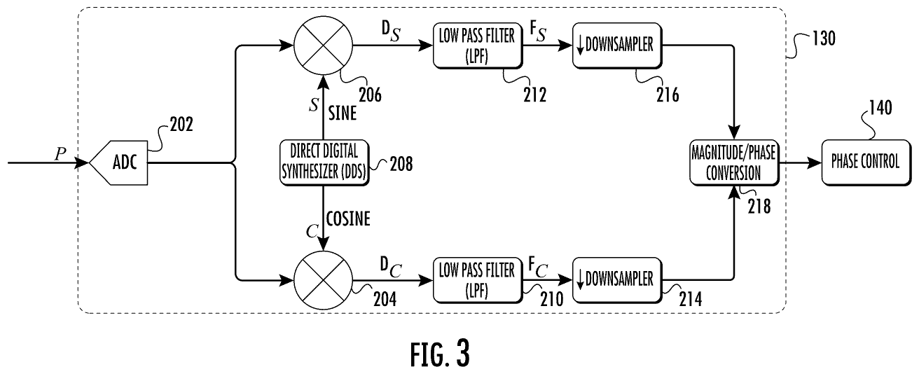

The RF signal is provided to the resonator 126-1 from an RF power assembly 128-1 that may be dedicated to provide the RF signal just to acceleration stage A1. In operation, when the RF signal is provided to the resonator coil 134 an oscillating voltage will be established at the powered drift tube 156 at the frequency of the RF signal. In the arrangement of FIG. 2, a pickup detector 136-1 is provided to monitor the RF signal that powers the powered drift tube 156. The pickup detector 136-1 may be arranged in a resonator enclosure 137 of the resonator 136-1. The pickup detector 136-1 is arranged to output an RF pickup signal to the phase measurement circuit 130. Details of an embodiment of the phase measurement circuit 130 are provided with respect to FIG. 3 to follow. Note that the frequency and phase of the pickup detector 136-1 will match the frequency and phase of the RF signal that is delivered to the resonator coil 134. The phase measurement circuit 130 may, for example, determine phase information related to the RF signal driving acceleration stage A1, based upon the RF pickup signal received from pickup detector 136-1. The phase information may be output to another component, such as a phase controller 140, which controller, in some embodiments, may feedback a control signal in a closed loop fashion, to adjust operation of the RF power assembly 128-1. Note that the phase control system 142 may also include other RF pickup detectors, individually arranged in the resonators of other acceleration stages of the LINAC 118, similarly to pickup detector 136-1. These additional detectors are shown as pickup detectors 136-2 to 136-N. Thus, the phase control system 142 may adjust operation of RF power assemblies of the power arrangement 128, either individually at a given acceleration stage, or collectively, over a plurality of the acceleration stages of the LINAC 118.

FIG. 3 shows details of an exemplary variant of the phase measurement circuit 130. As shown, the phase measurement circuit 130 may include an analog-to-digital converter (ADC), shown as ADC 202. The ADC 202 is coupled to receive an RF pickup signal, meaning an analog signal, and convert the RF pickup signal to a digital signal. Note that the ADC 202 may be coupled to receive a plurality of RF pickup signals from a plurality of RF pickup detectors that are arranged at a plurality of acceleration stages, respectively. Thus, in one embodiment where the ion implanter has a 10-acceleration-stage LINAC, 10 different RF pickup detectors may be arranged to generate and deliver 10 different RF pickup signals to the ADC 202 in parallel. Note that the phase measurement from the RF pickup signals from any given RF pickup detector may be done periodically, such as at the tuning or calibration stage.

The phase measurement circuit 130 may also include a digital synthesis circuit 208 that is coupled to output an oscillator signal to mix with the digital signal output by the ADC 202. The oscillator signal may be a complex sinusoidal signal that is mixed at a first mixer 204 and a second mixer 206, as shown. The oscillator signal may include a cosine function and sine function, wherein a digital cosine signal, referred to herein as a baseband in-phase (I) signal, and a digital sine signal, referred to herein as a baseband quadrature (Q) signal, are generated at the output of the first mixer 204 and the output of the second mixer 206. The digital synthesis circuit 208 may be field programmable gate array in one non-limiting embodiment.

As shown in FIG. 3, the phase measurement circuit 130 may further include a first low pass filter 210 to filter the digital cosine signal, to generate a filtered baseband in-phase signal, and a second low pass filter 212 to filter the digital sine signal, to generate a filtered baseband quadrature signal. Moreover, the phase measurement circuit 130 may include a first downsampler circuit 214 to sample the filtered baseband in-phase signal, and a second downsampler circuit 216 to sample the filtered baseband quadrature signal.

In operation, and as detailed further below, the digital synthesis circuit 208 will create a complex sinusoidal signal S at a baseband frequency that is lower than the frequency of the RF pickup signal P that is received from the ADC 202. The multiplication of the complex sinusoidal signal with the RF pickup signal then takes place at first mixer 204 and second mixer 206. The first lowpass filter 210 and the second low pass filter 212 may then pass a difference frequency while rejecting a set of sum frequency signals that may be passed through the first downsampler circuit 214 and the second downsampler circuit 216, before receipt at a phase conversion circuit 218. The phase conversion circuit 218 may then be used to determine phase information associated with a given RF signal at a given acceleration stage, such as a phase of the RF signal, amplitude of the RF signal, based upon a first output from the first downsampler circuit 214 and a second output from the second downsampler circuit 216.

In particular, an RF pickup signal P of frequency ωᵢ that is generated by the pickup detector 136 may be represented as

x(t)=A cos(ωᵢt) (1).

The RF pickup signal P may be passed through an analog to digital converter, and after transformation by the ADC 202 into a digital signal, mixed with an oscillator signal S of frequency ω₀ that is of the form cos(ω₀t) and −sin(ω₀t), and is output by the digital synthesis circuit 208, to yield a digital cosine signal D_{C} and a digital sine signal D_{S}. In turn, D_{C} will have the form

yᵢ(t)=A cos(ωᵢt)*cos(ω₀t) (2) and

D_{S} will have the form

y_{q}(t)=A cos(ωᵢt)*(−sin(ω₀t)) (3).

Eq (2) may be expressed as

yᵢt)=A(cos((ωᵢ−ω₀)t)/2+cos((ωᵢ+ω₀)t)/2) (4),

while Eq (3) may be expressed as

y_{q}(t)=A(−sin((ωᵢ+ω₀)t)/2+sin((ωᵢ−ω₀)t)/2) (5).

These digital signals, upon passing through the first low pass filter 210 and the second lowpass filter 212, will generate a filtered digital cosine signal F_{C}, and a filtered digital sine signal F_{S}, respectively. The filtered digital cosine signal may be expressed as

yᵢ(t)=A(cos((ωᵢ−ω₀)t))/2 (6) and

the digital filtered sine signal may be expressed as

y_{q}(t)=A(sin((ωᵢ−ω₀)t))/2 (7).

Thus, the frequency of these filtered signals is represented by the difference (ωᵢ−ω₀). Note that in the present embodiments the RF frequency of the RF pickup signal and the oscillator signal S will have the same frequency (such as 13.56 MHz or 27.12 MHz, according to non-limiting embodiments) so that ωᵢ−ω₀ is equal to zero and yᵢ(t) and y_{q}(t) will therefore have fixed values.

The filtered signals after downsampling are then used to determine phase information including the phase and magnitude of the RF pickup signal P, corresponding to the phase and magnitude of the given RF signal at the acceleration stage where the pickup detector 136-1 is located.

This phase information, such as a phase value, may then be used by the phase controller 140, to adjust the phase of the RF signal to a targeted phase value, as needed. This procedure may be used for any number of acceleration stages to generate phase information of the RF signals at the different acceleration stages, so that the phase information for the different acceleration stages is fed back to adjust the RF signals directed to each of the different acceleration stages. Note that, in accordance with some embodiments, the phase may be adjusted for an RF signal directed to any given acceleration stage, independently of the phase adjustment of RF signals sent to any other acceleration stage. In other non-limiting embodiment, the phases of RF signals delivered to different stages may be determined and taken into account in order to adjust the phases to the different acceleration stages in concert, to achieve an optimal calibration.

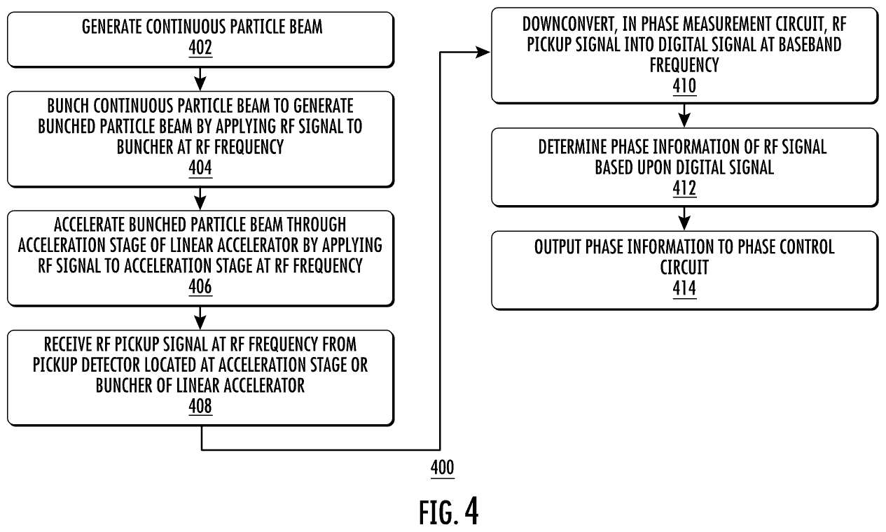

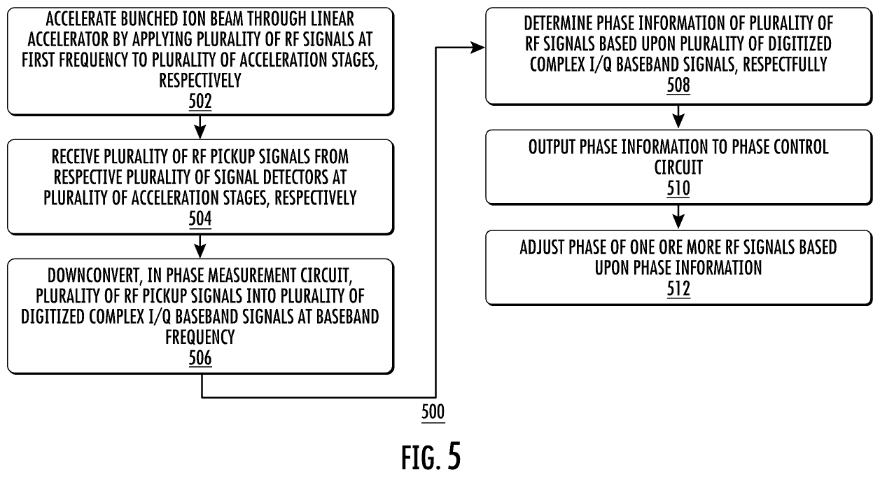

FIG. 4 shows an exemplary process flow 400, according to some embodiments. At block 402, a continuous particle beam is generated where the particle beam is a charged particle beam, such as an electron beam or ion beam.

At block 404 the continuous particle beam is bunched into a bunched particle beam. The bunching may take place at an upstream location of a linear accelerator using an RF voltage, as in known systems by applying an RF signal to the buncher at a RF frequency, such as 13.56 MHz, 27.12 MHz, or other suitable RF frequency.

At block 406, the bunched particle beam is accelerated through an acceleration stage of the linear accelerator by applying an RF signal to the acceleration stage at an RF frequency, such as 13.56 MHz, 27.12 MHz, or other suitable RF frequency.

At block 408, an RF pickup signal is received at the RF frequency from a pickup detector located at the acceleration stage of the linear accelerator. In one example, the pickup detector may be located in a resonator that is coupled to deliver the RF signal to a given acceleration stage or buncher.

At block 410, the RF pickup signal is downconverted by a phase measurement circuit into a complex baseband signal.

At block 412, phase information corresponding to the RF signal is determined based upon the digital signal. At block 414, the phase information is output to an external component, such as a phase control circuit.

FIG. 5 depicts an exemplary process flow 500 according to some embodiments of the disclosure. At block 502 a bunched ion beam is accelerated through a linear accelerator by applying a plurality of RF signals at a first frequency to a plurality of acceleration stages, respectively. As an example, each of the acceleration stages may apply an RF signal at 13.56 to a drift tube of the respective acceleration stage.

At block 504, a plurality of RF pickup signals are received from a respective plurality of signal detectors that are located at the plurality of acceleration stages, respectively.

At block 506, the plurality of RF pickup signals are downconverted in a phase measurement circuit, into a plurality of digitized complex I/Q baseband signals.

At block 508, phase information is determined for the plurality of RF signals based upon plurality of digitized complex I/Q baseband signals, respectively.

At block 510, the phase information is output to a phase control circuit, while at block 512, the phase of one or more of the RF signals is adjusted based upon the received phase information.

In view of the foregoing, at least the following advantages are achieved by the embodiments disclosed herein. A first advantage provided by the present embodiments is a self-contained measurement system that does not require separate metrology apparatus to measure RF signal phases at each acceleration stage. Another advantage is that the overall measurement and control system in a linear accelerator may be reduced in size in the present approach, and may be conveniently scaled up or down, as needed.

While certain embodiments of the disclosure have been described herein, the disclosure is not limited thereto, as the disclosure is as broad in scope as the art will allow and the specification may be read likewise. Therefore, the above description are not to be construed as limiting. Those skilled in the art will envision other modifications within the scope and spirit of the claims appended hereto.

1. A particle beam processing apparatus, comprising:
a particle beam source to generate a charged particle beam; and
a linear accelerator to generate a bunched particle beam from the charged particle beam, and accelerate the bunched particle beam, wherein the linear accelerator comprises:
a plurality of acceleration stages that accelerate the bunched particle beam; and
a phase control system, to individually measure a phase of an RF signal that is applied at a first frequency to a given acceleration stage of the plurality of acceleration stages, the phase control system comprising:
an RF signal pickup assembly, comprising a plurality of RF signal detectors, arranged separately in the plurality of acceleration stages; and
a phase measurement circuit, to convert an RF pickup signal, received from an RF signal detector of the RF signal pickup assembly, into a digital signal, for determining a phase of the RF signal.

2. The particle beam processing apparatus of claim 1, the phase measurement circuit comprising an analog-to-digital converter (ADC), coupled to receive the RF pickup signal and convert the RF pickup signal to a digital signal.

3. The particle beam processing apparatus of claim 2, the ADC coupled to receive a plurality of RF pickup signals from the plurality of acceleration stages, respectively.

4. The particle beam processing apparatus of claim 2, the phase measurement circuit further comprising a digital synthesis circuit, coupled to output an oscillator signal to mix with the digital signal, the oscillator signal comprising a cosine function and sine function, wherein an in-phase (I) baseband signal and quadrature (Q) baseband signal are generated.

5. The particle beam processing apparatus of claim 4, the phase measurement circuit further comprising a first low pass filter to filter the in-phase (I) baseband signal, to generate a filtered in-phase (I) baseband signal, and a second low pass filter to filter the quadrature (Q) baseband signal, to generate a filtered quadrature (Q) baseband signal.

6. The particle beam processing apparatus of claim 5, the phase measurement circuit further comprising:
a first downsampler circuit to sample the filtered in-phase (I) baseband signal;
a second downsampler circuit to sample the filtered quadrature (Q) baseband signal; and
a phase conversion circuit to determine a phase of the RF signal based upon a first output from the first downsampler circuit and a second output from the second downsampler circuit.

7. The particle beam processing apparatus of claim 1, further comprising a phase control circuit, coupled to receive, from the phase measurement circuit, a phase value corresponding to the RF signal, of the given acceleration stage, the phase control circuit further arranged to adjust the phase of the RF signal to a targeted phase value.

8. The particle beam processing apparatus of claim 7,
the phase control circuit being coupled to receive a plurality of phase values corresponding to a plurality of RF signals that are applied to the plurality of acceleration stages, respectively,
wherein the phase control circuit is arranged to adjust a respective phase of each of the plurality of RF signals, according to a set of targeted phase values to be applied to the plurality of acceleration stages, respectively.

9. The particle beam processing apparatus of claim 4, wherein the digital synthesis circuit comprises a field programmable gate array.

10. A method of operating a particle beam processing apparatus, comprising;
generating a continuous charged particle beam;
bunching the continuous charged particle beam into a bunched particle beam;
accelerating the bunched particle beam in a linear accelerator that comprises a plurality of acceleration stages; and
measuring a phase of an RF signal that is applied at a first frequency to a given acceleration stage of the plurality of acceleration stages, wherein the measuring comprises:
receiving a RF pickup signal from a signal detector of the given acceleration stage; and
converting the RF pickup signal to a digital baseband signal.

11. The method of claim 10, comprising receiving a plurality of RF pickup signals from the plurality of acceleration stages, respectively; and converting the plurality of RF pickup signals into a plurality of digital baseband signals.

12. The method of claim 10, comprising:
outputting an oscillator signal, comprising: a cosine function and sine function; and
mixing the oscillator signal with a digital signal derived from the RF pickup signal to form a complex baseband signal comprising an in-phase (I) baseband signal and quadrature (Q) baseband signal.

13. The method of claim 12, comprising:
passing the in-phase (I) baseband signal through a first low pass filter to generate a filtered in-phase (I) baseband signal; and
passing the quadrature (Q) baseband signal through a second low pass filter to generate a filtered quadrature (Q) baseband signal.

14. The method of claim 13, further comprising:
sampling the filtered in-phase (I) baseband signal at a first sampler;
sampling the filtered quadrature (Q) baseband signal at a second sampler; and
determining a phase of the RF signal based upon a first output from the first sampler and a second output from the second sampler.

15. The method of claim 10, further comprising:
receiving a phase value corresponding to the RF signal, of the given acceleration stage; and
adjusting the phase of the RF signal to a targeted phase value.

16. The method of claim 10, further comprising:
receiving a plurality of phase values corresponding to a plurality of RF signals that are applied to the plurality of acceleration stages, respectively; and
adjusting a respective phase of each of the plurality of RF signals, according to a set of targeted phase.

17. The method of claim 13,
wherein the RF signal is characterized as x(t)=A cos(ωᵢt),
wherein the oscillator signal is characterized by cos(ω₀t) and −sin(ω₀t),
wherein the filtered in-phase (I) baseband signal is given by yᵢ(t)=A cos((ωᵢ−ω₀)t)2, and
wherein the filtered quadrature (Q) baseband signal is given by y_{q}(t)=A sin((ωi−ω0)t)2.

18. The method of claim 11, wherein the signal detector is disposed in a resonator enclosure of the given acceleration stage.

19. A linear accelerator, comprising:
a buncher to generate a bunched particle beam from a charged particle beam;
a plurality of acceleration stages, to accelerate the bunched particle beam; and
a phase control system, to individually measure a phase of an RF signal that is applied at a first frequency to a given acceleration stage of the plurality of acceleration stages, the phase control system comprising:
an RF signal pickup assembly, comprising a plurality of RF signal detectors, arranged separately in the plurality of acceleration stages; and
a phase measurement circuit, to convert an RF pickup signal, received from an RF signal detector of the RF signal pickup assembly, into a digital baseband signal, for determining a phase of the RF signal.

20. The linear accelerator of claim 19, the phase measurement circuit comprising:
an analog-to-digital converter (ADC), coupled to receive the RF pickup signal and convert the RF pickup signal to a digital signal; and
digital synthesis circuit, coupled to output an oscillator signal to mix with the digital signal, the oscillator signal comprising a cosine function and sine function, wherein an in-phase (I) baseband signal and quadrature (Q) baseband signal are generated.
